(19) United States
(12) Patent Application Publication
(10) Pub. No.: US 2009/0308447 A1
(43) Pub. Date: Dec. 17, 2009

(54) PHOTOVOLTAIC MODULE WITH AT LEAST ONE CRYSTALLINE SOLAR CELL

(75) Inventor: Dirk Albrecht, Fehrbellin (DE)

Correspondence Address: SMITH PATENT OFFICE, 1901 PENNSYLVANIA AVENUE N W, SUITE 901, WASHINGTON, DC, 20006, US

(73) Assignee: SITEC Meldetechnik GmbH, Neuruppin (DE)

(21) Appl. No.: 12/300,286

(22) PCT Filed: May 10, 2007
(86) PCT No.: PCT/DE2007/000863

§ 371 Date: Mar. 10, 2009

(30) Foreign Application Priority Data
May 10, 2006 (DE) 10 2006 021 990.2

(51) Int. Cl. H01L 31/00

(52) U.S. Cl. 136/256

(57) ABSTRACT

The invention relates to a photovoltaic module, in which at least one crystalline solar cell, by means of which light energy can be converted into electrical energy, is arranged on a carrier substrate, characterized in that a contact area is formed between the carrier substrate and the at least one crystalline solar cell, wherein, in the region of the contact area, an outer surface on a light entry side of the at least one crystalline solar cell is in contact with a rear surface of the carrier substrate, and in that electrical connection contacts are arranged on the rear side of the at least one crystalline solar cell facing away from the light entry side.

The invention relates to a photovoltaic module comprising at least one crystalline solar cell.

### BACKGROUND OF THE INVENTION

A photovoltaic module or solar module serves for directly generating electrical power from sunlight. This technical device consists of a composite system comprising a plurality of components. It is possible to distinguish between on the one hand photovoltaic modules comprising amorphous solar cells, and on the other hand photovoltaic modules in which a previously produced crystalline solar cell is arranged on a carrier substrate. In the photovoltaic modules comprising amorphous solar cells, as used for example in the document DE 40 26 165 C2, the solar cells are deposited step-by-step on a carrier substrate, for example by means of thin-layer technology, in order thus to create the layer structure which performs the energy conversion. The carrier substrate, for example glass, then forms in practice an inherent and necessary component of the amorphous solar cells produced.

In contrast thereto, crystalline solar cells comprise as the photoactive element a crystalline material, usually in the form of a crystalline semiconductor such as silicon for example. Crystalline solar cells are firstly produced in a separate production process, in order then to be integrated subsequently as already existing components into photovoltaic modules.

When using crystalline solar cells for the photovoltaic module, usually a material composite is provided which consists of glass as carrier material, an embedding or encapsulating material for holding the actual crystalline solar cell together with the wiring, and a rear-side construction or cover. The encapsulating material serves to protect the crystalline solar cell against mechanical and chemical influences. In particular, permeability to water vapour is a problem for solar cells. Corrosion of the metal contacts (current collectors) leads to the failure of individual solar cells or to the failure of the module, since the solar cells are connected in series. In most of the presently commercially available photovoltaic modules comprising crystalline solar cells, the material EVA (ethyl vinyl acetate) is used. This has the property of melting at 150° C. and as a result enclosing the solar cell and the connectors without any bubbles. At the same time, a thermal crosslinking of the material takes place. Apart from EVA, other materials are also used.

It is known from the document EP 0 436 205 A2 to cure methyl methacrylate by means of UV light or daylight. According to the document DE 198 46 160 A1, crystalline solar cells are embedded in a hot-melt film. In the document DE 203 02 045 U1, a PVB film (polyvinyl butyral film) is used to adhesively bond the solar cells.

Approximately 30% of the costs arise from the process of producing the photovoltaic modules comprising crystalline solar cells from the individual components. These costs are caused by the high proportion of production steps that cannot be automated, and by long process times during lamination of the end product. EVA as the standard material requires approximately 15 to 30 min for crosslinking. During this time, the production machine is occupied and cannot be used for any further product. A continuous production process is not possible.

A further disadvantage of EVA is that it does not possess long-term UV resistance. An EVA layer is located between the glass plate and the crystalline solar cell, i.e. in the optically active region. The sunlight has to pass through this zone. Module service lives are at least 20 years. During this time, the EVA ages as a result of chemical degradation. Newer EVA materials lose approximately 20% of their light permeability during this time. As a result, a drop in performance of the module will also be seen. The other proposed materials also have this problem. Attempts have been made to avoid this by using UV stabilizers. However, this only slows down the ageing process.

A further disadvantage of all the described encapsulating materials is that they are plastics. Plastics have a much higher thermal expansion coefficient (50 to 150×10⁻⁶ K⁻¹) than silicon (2×10⁻⁶ K⁻¹) or glass (4×10⁻⁶ K⁻¹). If photovoltaic cells made from silicon are to be encapsulated with plastics, the crystalline solar cells must be mechanically decoupled from the plastic by means of suitable soft adhesive layers. EVA solves this problem only to an insufficient extent.

All the proposed materials have in common the fact that they require a laminating operation as one processing step. As a result, a permanent fixed and sealed connection of the layers is achieved under the effect of pressure and temperature. During this, the plastic material is heated to temperatures at which it can at least be deformed. A number of undesirable effects arise in the process, for example the displacement of the crystalline solar cells in the laminator, the escape of material at the module edges, a non-uniform layer structure in height terms, and the incorporation of mechanical stresses at the solar cell connectors. Failures of photovoltaic modules having these sources of error are sufficiently well known. This laminating process causes high process times and thus high costs, is difficult to automate, and faulty laminates can no longer be repaired.

A further disadvantage of this technology is the rear-side structure of the photovoltaic module. Once again, plastics are used here, for example composite films made from PVF (polyvinyl fluoride)—PET (polyethylene terephthalate)—PVF or PVF—aluminium—PVF. However, plastics have the property of being poor heat conductors. In sunlight, the modules heat up to 80° C. Due to the negative temperature coefficient of a solar cell, the performance and thus the efficiency of the module are reduced. The heat dissipation from the solar cell is completely insufficient.

### SUMMARY OF THE INVENTION

The object of the invention is to provide a photovoltaic module comprising at least one crystalline solar cell, in which the optical, mechanical and chemical properties are improved and the production is fast, inexpensive and capable of being highly automated.

This object is achieved by a photovoltaic module according to independent claim 1. Advantageous embodiments of the invention form the subject matter of dependent claims.

According to the invention, a photovoltaic module is provided in which at least one crystalline solar cell, by means of which light energy can be converted into electrical energy, is arranged on a carrier substrate, a contact area is formed between the carrier substrate and the at least one crystalline solar cell, wherein, in the region of the contact area, an outer surface on a light entry side of the at least one crystalline solar cell is in contact with a rear surface of the carrier substrate, and electrical connection contacts are arranged on the rear side of the at least one crystalline solar cell facing away from the light entry side.

The carrier substrate is made for example from glass or plastic, for example polycarbonate. The crystalline solar cell is applied to the carrier substrate without any additives, i.e. without adhesion promoters. As a result, the front side of the crystalline solar cell is free and thus can bear flat against the carrier substrate in the region of the contact area. The crystalline solar cell has direct contact with the carrier substrate. This has the advantage that there are no optical components between the carrier substrate and the solar cell front side. This therefore avoids the optical influence of the encapsulating material on the front side, as provided in the prior art. Since no material is now located at this point, no ageing process of the optical medium takes place on the front side of the solar cell, but rather an unhindered passage of the sunlight towards the active solar cell. The reduction in performance observed in known photovoltaic modules comprising crystalline solar cells, which according to experience is up to 20% in 20 years, is thus avoided. The service life and the reduction in performance thus depend only on the quality of the solar cell itself. The result is a considerable improvement in the long-term endurance of photovoltaic modules.

One advantageous further development of the invention provides that the contact area is formed essentially over the entire outer surface on the light entry side of the at least one crystalline solar cell.

In one advantageous embodiment of the invention, it may be provided that the contact area is formed as an essentially continuous contact area.

In one preferred embodiment of the invention, an edge seal which at least partially surrounds the contact area is provided.

Advantageously, one further development of the invention provides that the edge seal is formed so as to at least assist a fixing of the at least one crystalline solar cell to the carrier substrate.

One advantageous embodiment of the invention may provide that the edge seal seals off the contact area from an external environment in a fluid-tight manner.

Preferably, in one further development of the invention, the edge seal extends into corner regions in which side faces of the at least one crystalline solar cell and the rear surface of the carrier substrate butt against one another.

One advantageous further development of the invention provides that the edge seal extends into a region of the rear side of the at least one crystalline solar cell facing away from the light entry side.

In one advantageous embodiment of the invention, it may be provided that the edge seal optionally essentially completely covers the surface of the at least one crystalline solar cell on the rear side. In this way, a mechanical protection is improved, in particular for the entire solar cell and the electrical contacts. Furthermore, the thermal coupling of the crystalline solar cell to a rear-side structure is made easier.

In one preferred embodiment of the invention, a heat-distributing and heat-dissipating system is provided for thermal energy generated on the at least one solar cell. During production of the photovoltaic module, in one example of embodiment the heat-distributing and heat-dissipating system is applied as a layer composite.

Advantageously, one further development of the invention provides that the heat-distributing and heat-dissipating system comprises a heat-conducting layer made from a heat-conducting material which is thermally coupled to the at least one crystalline solar cell.

One advantageous embodiment of the invention may provide that the heat-conducting material is a plastic material.

Preferably, in one further development of the invention, the heat-conducting layer is thermally coupled to the at least one crystalline solar cell via an adhesion promoter on the rear side of the at least one crystalline solar cell facing away from the light entry side.

One advantageous further development of the invention provides a module rear-side cover made from a further heat-conducting material.

In one preferred embodiment of the invention, it is provided that the further heat-conducting material is a metal or a metal alloy.

Advantageously, one further development of the invention provides that the further heat-conducting material is formed as a film or as a plate.

In one advantageous further development of the invention, it may be provided that the carrier substrate is provided with an optical anti-reflection coating at least on one side. Such anti-reflection coatings are known per se in various embodiments. The coating may be formed on the side of the carrier substrate facing towards or facing away from the crystalline solar cell, said carrier substrate preferably being made from glass. The coating may also be provided on both sides. In the various embodiments, a coupling-in of the sunlight impinging on the solar cell is thus achieved with lower losses.

One advantageous embodiment of the invention may provide that at least one further crystalline solar cell is formed which is optionally mounted analogously to the at least one crystalline solar cell, wherein the at least one further crystalline solar cell and the at least one crystalline solar cell are connected to one another via electrical connection contacts on the respective rear side facing away from the light entry side.

### DESCRIPTION OF PREFERRED EXAMPLES OF EMBODIMENTS OF THE INVENTION

The invention will be explained in more detail below on the basis of examples of embodiments and with reference to the figures of a drawing, in which:

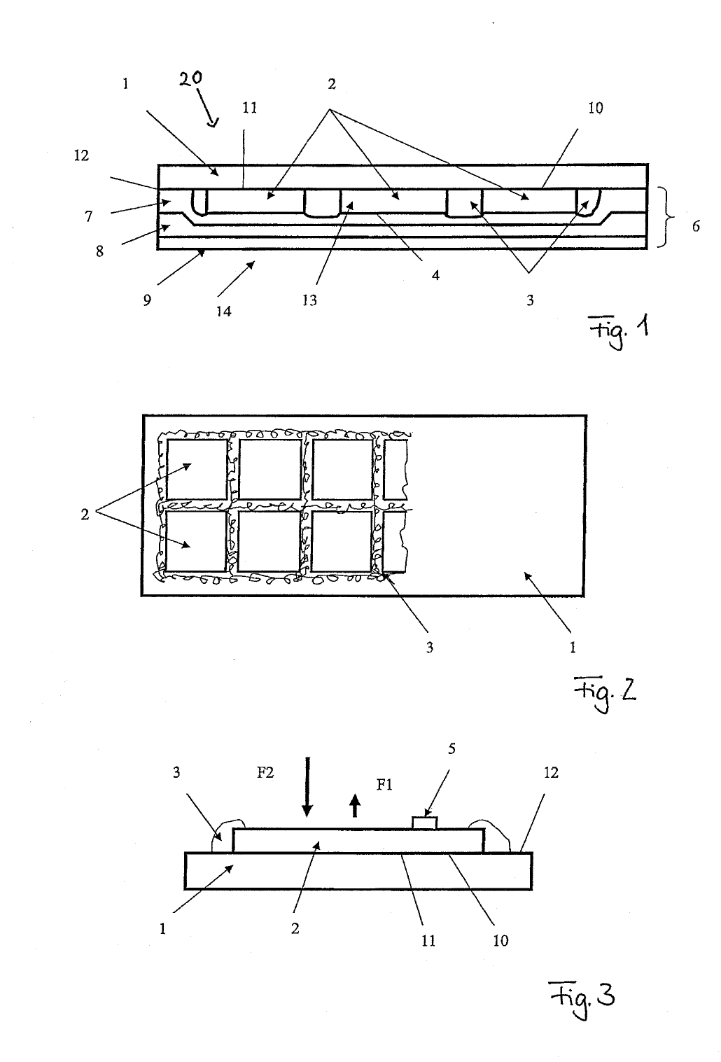

FIG. 1 shows, from above, an arrangement comprising a carrier substrate for a photovoltaic module and a plurality of crystalline solar cells arranged thereon;

FIG. 2 shows, in cross section, a detail of the arrangement of FIG. 1; and

FIG. 3 shows, in cross section, a photovoltaic module using the arrangement of FIG. 1.

FIG. 1 shows, from above, an arrangement comprising a carrier substrate 1 for a photovoltaic module 20 and a plurality of solar cells 2 arranged thereon and of a so-called crystalline type. The solar cells 2, which comprise a crystalline photoactive material, are arranged flat next to one another at a small distance of approximately 2 to 3 mm. Once the solar cells 2 have been positioned, a respective edge seal 3 is applied around the solar cells 2. With this structure, a fluid-tight sealing of the solar cells 2 with respect to the carrier substrate 1 is achieved, so that a contact area is formed in particular in an air-tight manner between the solar cells 2 and the carrier substrate 1.

FIG. 2 shows, in cross section, the configuration of the edge seal 3 for a section of the arrangement of FIG. 1. This sealing leads to an effect comparable to that of the known “Magdeburg hemispheres”. The force F1 opposes the force F2 (air pressure). It is not possible to detach the solar cells 2 again from the carrier substrate 1. In experiments, detachment was not possible even at forces of up to 500 kg/cm².

In an alternative embodiment (not shown), the edge seal 3 is applied such that it partially or completely covers the surface of the rear side 4 of the solar cells 2. This allows a technologically simple production. The region between the solar cells 2 is filled with adhesive, i.e. a wall sealing is carried out. At the same time, the rear side of the cell is adhesively bonded to the electrical connectors, for example by means of a flat adhesive film or a liquid adhesive. This can preferably be carried out in one technological production step.

FIG. 3 shows, in cross section, a photovoltaic module 20 using the arrangement of FIG. 1.

Once all the solar cells 2 have been positioned and sealed, the solar cells 2 are contacted and connected on the rear side 4 via connection contacts 5. As a further layer, a laminate structure or layer composite 6 is applied which consists of an adhesive layer 7 having a thickness of up to approximately 0.2 mm, a thermally conductive insulating film layer 8, which is made for example from polyimide, and a rear-side cover 9 consisting of a metal layer, preferably aluminium. By using a metal, a rear-side cover 9 is obtained which is stable against weathering and impermeable to water and oxygen.

In the region of an outer surface 10 of the solar cells 2 on a light entry side, a respective contact area 11 is formed, where the outer surface 10 is in direct contact with a rear surface 12 of the carrier substrate 1, without an adhesion promoter being provided.

The laminate structure 6, which in other embodiments may comprise further layers, performs in particular thermal functions. By incorporating the thermally conductive insulating film layer 8 directly on the solar cells 2 by means of the adhesive layer 7 serving as adhesion promoter, a heat exchange takes place between the solar cells 2 and the rear-side cover 9 made from aluminium. As a result, a better heat transfer from a front side 13 of the solar cells to a rear side 14 of the photovoltaic module 20 is achieved, and as a result a uniform heat distribution and cooling of the photovoltaic module 20. The heat distribution is highly advantageous since partial switch-offs of the photovoltaic module 20 may lead to heating or so-called hot spot effects in the solar cells 2. The latter overheat thermally and may in some cases be destroyed. In the case of a hot spot, a solar cell 2 partially heats up locally to such a degree that detachments of the laminate structure 6 from the carrier substrate 1 may take place, which leads to an optically defective photovoltaic module 20. This effect is avoided by means of the described structure of the photovoltaic module 20, since instances of local heating can be distributed across the entire photovoltaic module 20 due to the thermal conductivity of the rear side.

The rear-side cover 9 made from metal also performs the function of a cooling element for a module connector socket. In the photovoltaic module 20, bypass diodes (not shown) are used to switch off rows of solar cells. The bypass diodes generate heat when flowed through by current. The heat is transferred in the photovoltaic module 20 to the rear-side cover 9 and from there is discharged, thereby achieving the necessary cooling for the bypass diodes.

The laminate structure 6 may be applied in individual steps during production or may preferably be applied as a pre-prepared sub-product in one process step. All the explained steps of the method for producing the photovoltaic module 20 described by way of example in one embodiment above can be automated, are easy to reproduce and have short process times. Any mistakes can be repaired up to the point of applying the rear-side cover 9.

The features of the invention which are disclosed in the above description, the claims and the drawing may be important both individually and in any combination for implementing the invention in its various embodiments.

1. A photovoltaic module, in which at least one crystalline solar cell, by means of which light energy can be converted into electrical energy, is arranged on a carrier substrate, characterized in that a contact area is formed between the carrier substrate and the at least one crystalline solar cell, wherein, in the region of the contact area, an outer surface on a light entry side of the at least one crystalline solar cell is in contact with a rear surface of the carrier substrate, and in that electrical connection contacts are arranged on the rear side of the at least one crystalline solar cell facing away from the light entry side.

2. The photovoltaic module according to claim 1, wherein the contact area is formed essentially over the entire outer surface on the light entry side of the at least one crystalline solar cell.

3. The photovoltaic module according to claim 1, wherein the contact area is formed as an essentially continuous contact area.

4. The photovoltaic module according to claim 1, further comprising an edge seal which at least partially surrounds the contact area.

5. The photovoltaic module according to claim 4, wherein the edge seal is formed so as to at least assist a fixing of the at least one crystalline solar cell to the carrier substrate.

6. The photovoltaic module according to claim 4, wherein the edge seal seals off the contact area from an external environment in a fluid-tight manner.

7. The photovoltaic module according to claim 4, wherein the edge seal extends into corner regions in which side faces of the at least one crystalline solar cell and the rear surface of the carrier substrate butt against one another.

8. The photovoltaic module according to claim 4, wherein the edge seal extends into a region of the rear side of the at least one crystalline solar cell facing away from the light entry side.

9. The photovoltaic module according to claim 8, wherein the edge seal optionally essentially completely covers the surface of the at least one crystalline solar cell on the rear side.

10. The photovoltaic module according to any claim 1, further comprising a heat-distributing and heat-dissipating system for thermal energy generated on the at least one crystalline solar cell.

11. The photovoltaic module according to claim 10, wherein the heat-distributing and heat-dissipating system comprises a heat-conducting layer made from a heat-conducting material which is thermally coupled to the at least one crystalline solar cell.

12. The photovoltaic module according to claim 11, wherein the heat-conducting material is a plastic material.

13. The photovoltaic module according to claim 11, wherein the heat-conducting layer is thermally coupled to the at least one crystalline solar cell via an adhesion promoter on the rear side of the at least one crystalline solar cell facing away from the light entry side.

14. The photovoltaic module according to claim 1, further comprising a module rear-side cover made from a further heat-conducting material.

15. The photovoltaic module according to claim 14, wherein the further heat-conducting material is a metal or a metal alloy.

16. The photovoltaic module according to claim 14, wherein the further heat-conducting material is formed as a film or as a plate.

17. The photovoltaic module according to claim 1, wherein the carrier substrate is provided with an optical anti-reflection coating at least on one side.

18. The photovoltaic module according to claim 1, further comprising at least one further crystalline solar cell which is optionally mounted analogously to the at least one crystalline solar cell, wherein the at least one further crystalline solar cell and the at least one crystalline solar cell are connected to one another via electrical connection contacts on the respective rear side facing away from the light entry side.
